(19) United States
(12) Patent Application Publication
(10) Pub. No.: US 2012/0200324 A1
(43) Pub. Date: Aug. 9, 2012

(54) Frequency Offset Tracking and Jitter Reduction Method Using Dual Frequency-locked Loop and Phase-locked Loop

(76) Inventor: Hui Wang, Arlington, TX (US)

(21) Appl. No.: 13/021,675

(22) Filed: Feb. 4, 2011

(51) Int. Cl. H03L 7/08

(52) U.S. Cl. 327/156

(57) ABSTRACT

A method is provided for tracking large static or low-frequency frequency offset, such as SSC, in clock recovery of data communication or phase-locked loops based on a dual frequency-locked loop and phase-locked loop architecture. Instant PFD outputs are filtered to separate the phase errors due static/low-frequency frequency offset from the other phase mis-alignment. The static/low-frequency instant errors are used to drive a frequency-locked loop to track out static/low-frequency frequency offset completely. The phase-locked loop only needs to track the instant phase alignment other than the static/low-frequency frequency offset. Its gain or loop bandwidth does not need to be high so that the intrinsic jitter due to high gain or loop bandwidth can be avoided.

### TECHNICAL FIELD

This invention is related to the field of clock and data recovery lock tracking in data communication or phase-locked loop and, more specifically, to maintain phase lock with large static or modulated frequency offset with reduced jitter by using a dual frequency-locked loop and phase-locked loop technique.

### DISCUSSION OF RELATED ART

Modern high-speed data communication system designs have widely adopted the use of clock recovery with clock timing embedded within a received raw data stream. It offers higher data rate, better reliability, lower noise generation, higher noise immunity and lower power cost. To further reduce Elctro-Magnetic Interference (EMI), techniques such as Spread Spectrum Clocking (SSC) are utilized to distribute the energy over a frequency band. The clock frequency is modulated at a low frequency, such as 30 kHz to 33 kHz in PCI-Express, with a predefined waveform, such as a saw-tooth waveform, at a certain frequency modulating amplitude, such as up to 5000 ppm in PCI-Express.

In general, the receiver clock frequency can be different from the transmitter embedded clock frequency. On top of the static frequency offset, the SSC modulation between the transmitter and receiver can be asynchronous, and further increases the instant frequency offset between the transmitter and the receiver. For example, in PCI-Express interface, the static frequency offset can be 600 ppm, and the maximum peak-to-peak modulated frequency offset can be 10000 ppm (5000 ppm each on the transmitter and the receiver respectively).

Common methods are to increase the clock recovery loop gain or bandwidth to be able to track the large instant frequency offset. Large clock recovery bandwidth increases the high-frequency jitter in the recovered clock due to the large loop gain. There is a need for the clock recovery to be able to track large low-frequency frequency offset and not increase recovered clock jitter at the same time.

### SUMMARY

Consistent with embodiments of the present invention, methods of a dual frequency-locked loop and phase-locked loop for large frequency offset tracking with reduced jitter are provided. In some embodiments, a method comprises using a phase frequency detector to generate the instant phase frequency error, determining the low-frequency instant frequency offset by filter the instant phase frequency error with a low-pass filter and high-frequency instant phase frequency error by subtracting the low-frequency phase frequency error from the total instant frequency offset, using the low-frequency instant phase frequency error in a low-bandwidth frequency-locked loop to track the low frequency static or modulated frequency offset, feed the high-frequency instant phase frequency error and frequency-locked loop output to a normal bandwidth phase-locked loop to track the high-frequency instant phase frequency error. The normal bandwidth phase-locked loop does not need to have a high gain or large bandwidth, and the intrinsic jitter associated with high loop bandwidth is avoided.

### BRIEF DESCRIPTION OF THE DRAWINGS

Embodiments of this invention will be described in detail below with reference to the accompanying drawings. This invention may, however, be embodied in many different forms and should not be construed as being limited to the embodiments set forth herein.

FIG. 1 shows a diagram illustrating a interpolator-based clock and data recovery module in data communication.

FIG. 2 illustrates an example of instant frequency offset with static offset and SSC modulation.

FIG. 3 illustrates diagram of dual frequency-locked loop and phase-locked loop

### DETAILED DESCRIPTION

In the following description, specific details are set forth describing the embodiments disclosed herein. It will be apparent, however, to one skilled in the art that some embodiments may be practiced without some or all of these specific details. The specific embodiments disclosed herein are meant to be illustrative but not limiting. One skilled in the art may realize other material that, although not specifically described therein, is within the scope and the spirit of this disclosure.

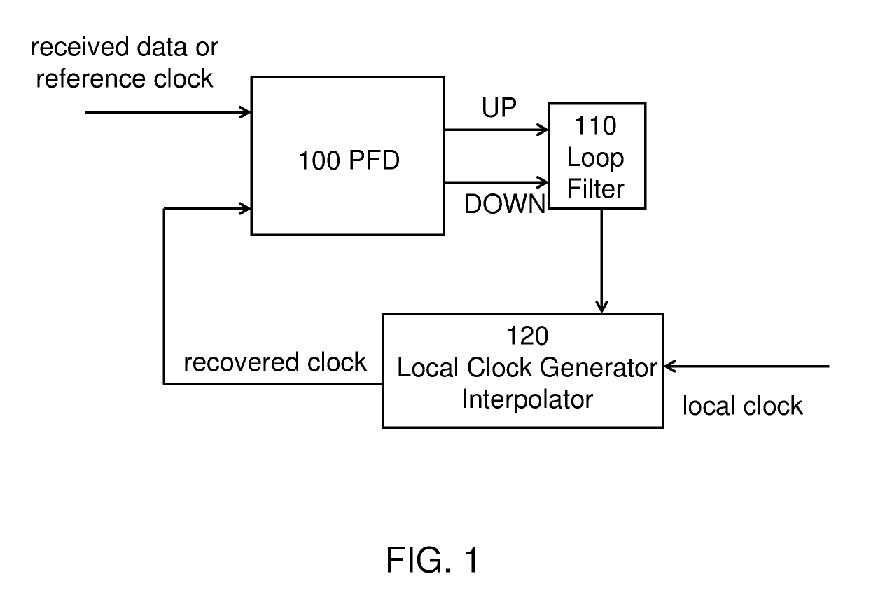

Generally, a phase frequency detector compares the phase and frequency of a local clock signal with the phase and frequency of a reference clock signal which can be either the embedded timing of the received data or a clock signal. A clock and data recovery module in data communication systems is illustrated in FIG. 1. As shown in FIG. 1, a PFD 100 is used to detect the instant phase and frequency error signal to delay or advance the local clock through an interpolator 120 to align the recovered clock with the embedded timing of the received data. PFD 100 outputs UP or DOWN pulses according to instant phase frequency error, and are filtered by Loop Filter 110. The filtered signal is used to control the frequency and phase of clocks from Local Clock Generator 120 to complete the feedback loop. Interpolators using multiple clock phases are widely used as the Local Clock Generator due to its ease of implementation.

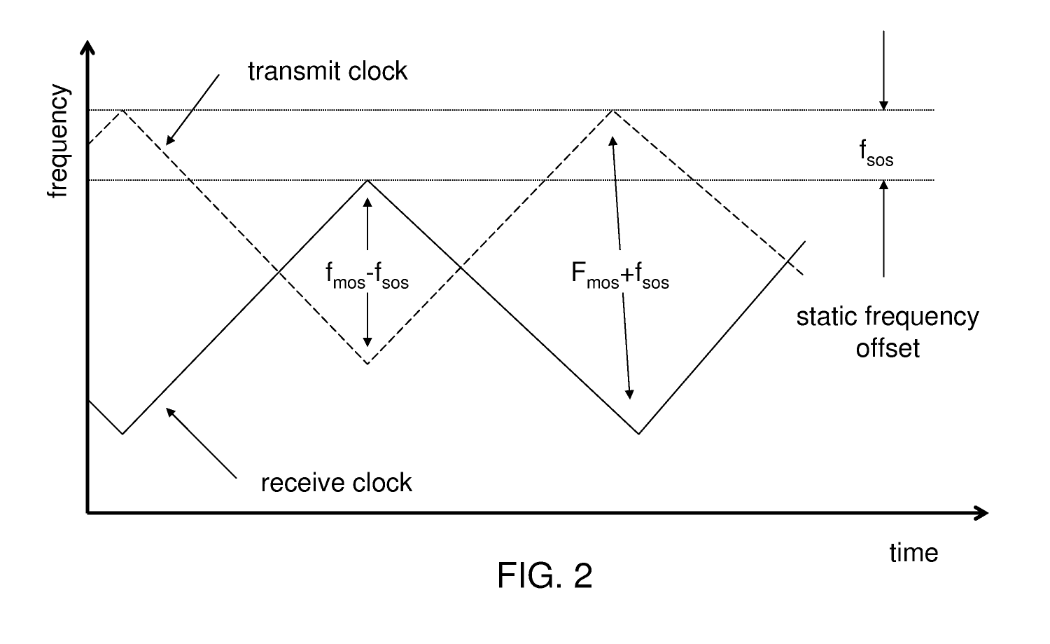

FIG. 2 shows an example of frequency offset between a transmitter and a receiver. There is normally a static frequency offset fₛₒₛ between the transmitter and receiver, for example, fₛₒₛ can be 600 ppm in PCI-Express. On top of the static frequency offset, there is also a frequency modulation to both the transmitter and the receiver clocks. The modulation frequency is normally low, such as 30 kHz to 33 kHz in PCI-Express, and the modulation amplitude can be high, such as 5000 ppm in PCI-Express. The modulating signal can be periodic, such as a triangular signal in PCI-Express. The modulation of SSC between the transmitter and the receiver can be asynchronous. The maximum instant modulation frequency offset fₘₒₛ between the transmitter and the receiver can thus be as high as twice the required modulation amplitude, such as 10000 ppm in PCI-Express. The total instant frequency offset is the sum of the static frequency offset fₛₒₛ and the modulation frequency offset fₘₒₛ. In order to track such a large instant frequency offset, the loop bandwidth of a typical 2^{nd}-order clock recovery loop is normally increased so that the frequency offset can be tracked by the large proportional gain. This also increases the intrinsic jitter of the clock recovery loop. The loop bandwidth is also limited by stability requirement due to the latency of the PFD in an interpolator-based clock recovery architecture. Increasing bandwidth is not feasible in such cases.

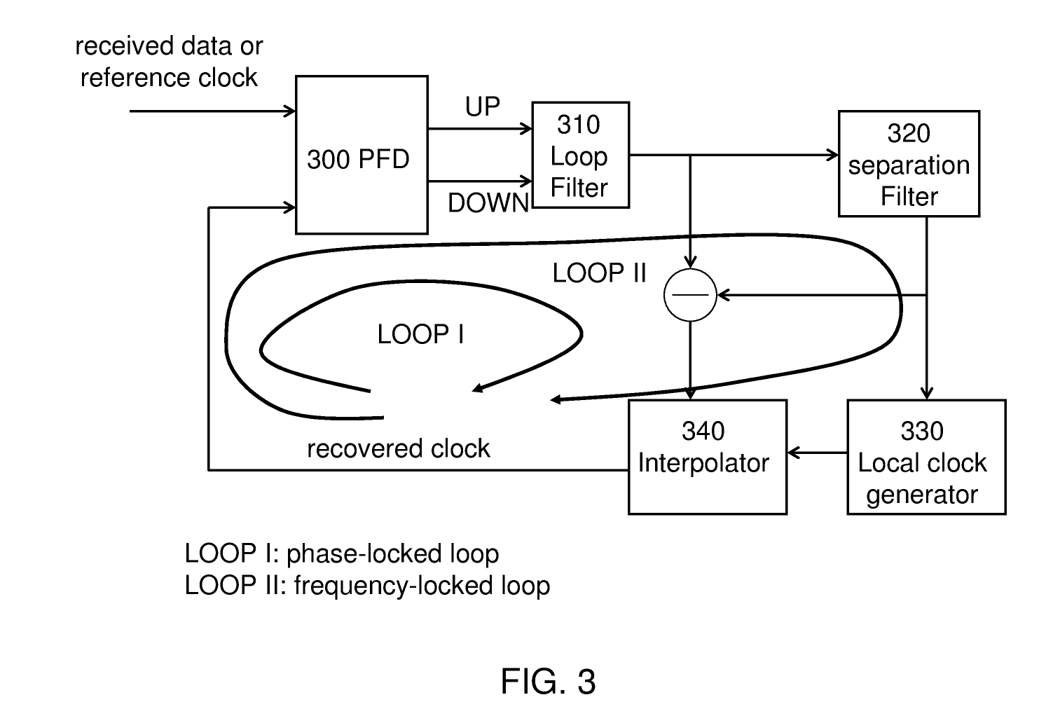

FIG. 3 illustrates the diagram of the dual frequency-locked loop and phase-locked loop. In this architecture, phase frequency detector 300 generates instant phase error Error by comparing the timing between the feedback clock and the reference input, such as a data stream or a reference clock. The instant phase frequency error content Error_{if} due to static or low-frequency frequency offset is separated by a low-pass filter 320. The other high-frequency instant phase frequency error content Error_{hf} is obtained by subtracting Error_{if} from the total instant phase error Error. Error_{if} is used to advance or delay the phase of a local clock generator 330 so that the frequency of the local clock tracks the reference clock frequency with 0 ppm static or low-frequency frequency offset. Error_{hf} is used to advance or delay the phase of the clock signal from the frequency-locked loop through an adjustable delay element 340, such as an interpolator, to track any instant phase misalignment between the reference input and the feedback clock. The frequency-locked loop can completely track out the static or low-frequency frequency offset. The bandwidth of the phase-locked loop does not need to be very high because it does not need to track the large static or low-frequency frequency offset.

Some embodiments of the current invention apply to either clock recovery application or phase-locked loop. The frequency-locked loop can be implemented as either a digital or an analog loop with either a digital or analog filter.

Some other embodiments may include adjusted loop filter bandwidth for separation of different low-frequency frequency offsets

The foregoing description is intended to illustrate, but not to limit, the scope of the invention, which is defined by the scope of the appended claims. Other embodiments are within the scope of this disclosure.

What is claimed is:

1. A method of dual frequency-locked loop and phase-locked loop comprising, dual loops for tuning the frequency and phase of local clock signal(s); and
determining instant phase errors of local clock and embedded clock; and
separating or filtering the instant phase errors into different frequency contents; and
tracking the large static or low-frequency frequency offset with low frequency error contents in a frequency-locked loop; and
tracking the phase mis-alignment in a phase-locked loop;
wherein the separation of frequency contents can be set according to the modulation frequency.

2. A method of claim 1, wherein the method is operated by a computer.

3. A method of claim 1, the static/low-frequency and high-frequency instant phase frequency errors, and filter bandwidth are stored in a computer readable media.

4. A method of claim 1, wherein the adjustable phase delay element can be implemented with a delay chain or other voltage/current controlled phase delay elements instead of an interpolator.

5. A method of claim 1, further comprising:
Using a different type of phase or frequency detector to generate digital, analog or mixed-signal instant phase errors.

6. A method of claim 1, further comprising:
Using an frequency-locked loop in an analog form, such as a analog voltage or current-controlled oscillator or voltage or current-controlled phase delay element

7. A method of claim 1, further comprising:
Using an frequency-locked loop in a digital form, such as a digitally voltage or current-controlled oscillator or voltage or current-controlled phase delay element

8. A method of claim 1, further comprising:
Using a phase-locked loop in an analog form, such as a analog voltage or current-controlled phase delay element

9. A method of claim 1, further comprising:
Using a phase-locked loop in a digital form, such as a digitally voltage or current-controlled phase delay element

10. A method of claim 1, further comprising:
An N-bit A/D converter to interface between an analog PFD with a digital filter or an N-bit D/A converter to interface a digital PFD with an analog filter

11. A method of claim 1, the instant phase error can be filtered and compared in a digital or an analog format.

12. A method of claim 1, further comprising:
the loop filter for the frequency-locked loop and phase-locked loop can be placed either in front of the separation filter or after the separation filter to separate the instant phase frequency errors due to static or low-frequency frequency offset.
